(19) United States
(12) Patent Application Publication
(10) Pub. No.: US 2008/0146449 A1
(43) Pub. Date: Jun. 19, 2008

(54) ELECTRICAL DEVICE AND METHOD OF MANUFACTURING SAME

(76) Inventors: Jerome Lesueur, Gif sur Yvette (FR); Nicolas Bergeal, Paris (FR); Giancarlo Faini, Paris (FR); Xavier Grison, Montigny le Bretonneux (FR); Marco Aprili, Palaiseau (FR)

Correspondence Address: LOWE HAUPTMAN & BERNER, LLP, 1700 DIAGONAL ROAD, SUITE 300, ALEXANDRIA, VA, 22314, US

(21) Appl. No.: 11/610,972

(22) Filed: Dec. 14, 2006

(51) Int. Cl. H01L 39/22

(52) U.S. Cl. 505/162; 430/5; 505/190; 257/31

(57) ABSTRACT

A method of making a superconductor device is described. The method comprises forming a layer of superconductive material, forming a first mask over part of the layer of superconductive material, irradiating the layer of superconductive material through the first mask with first ions such that a first portion having superconductive properties and a second portion having electrical insulating properties are formed in the layer of superconductive material, the first mask overlying the first portion, forming a second mask on a portion of the layer of superconductive material, defining a slit in the second mask, and irradiating the layer of superconductive material through the second mask with second ions to disorder atoms in a portion of the layer of superconductive material underlying the slit such that the critical superconducting temperature of the portion of layer of superconductive material exposed through the slit is lowered relative to the critical superconducting temperature of the portion of the layer protected by the second mask.

A method of making a magnetic circuit device is also described. The method comprises forming a layer of manganite material; forming a mask over part of the layer of manganite material; and irradiating the layer of manganite material through the mask with ions such that a portion of the layer of manganite material not underlying the mask has its conductive properties altered by the ions.

The present invention relates to an electrical device and a method of manufacturing the same; particularly but not exclusively the invention relates to a superconductor device or a magnetic circuit device and methods of making the same.

### BACKGROUND OF THE INVENTION

Superconductivity is commonly known as the complete loss of electrical resistance of a material at a well defined temperature. The transition temperature below which a material begins to demonstrate superconductivity is commonly known as the superconducting critical temperature T_{c} and is usually of the order of a few degrees Kelvin.

An example of a device relying on superconductivity is a Superconducting Quantum Interference Device (SQUID). A SQUID is generally seen as a magnetic flux to voltage transducer characterized by its function transfer dV/dφ (V is the voltage across the SQUID and φ is the magnetic flux through the loop). A SQUID can be used as a sensor of magnetic flux, current, voltage or energy, in a broad range of applications including susceptometry, voltmetry, non-destructive evaluation, nuclear magnetic resonance, geophysics and bio magnetism. Currently, SQUIDs made of superconducting metals or alloys are the most widely developed superconducting devices.

Nb/Al₂O₃/Nb trilayer junction technology is currently used for most applications. Such SQUIDs have achieved impressive sensitivity (a few fT/Hz^{-1/2}). However, the very low transition temperature Tc of superconducting metals and alloys make them inappropriate for many applications.

The discovery of superconductivity in metal oxides, such as Lanthanum-based oxides, by J. G Bednorz and K. A Mueller in 1986 resulted in a major improvement in the superconducting transition temperature. It was followed by the discovery of a superconducting compound (YBa₂Cu₃O₆₊ₓ), where 0≦x≦1 which demonstrates superconductivity above 77 K, the boiling temperature of liquid nitrogen. Since the critical or transition temperatures T_{c} of these new compounds are much greater than the T_{c} of superconducting metals and alloys, they are generally referred as High T_{c} superconductors (HTSc) and belong to a family referred to as “oxide superconductors”. A majority of them are copper oxides, their main characteristics being the presence of CuO₂ layers which provide most of their electronic properties.

This major improvement in the transition temperature T_{c} of superconductors resulted in further development of superconductor applications operating at temperatures that could be obtained easily by means of a cryo-cooler or liquid nitrogen. In particular, there has been intensive effort to make SQUIDs operable at such temperatures.

A Josephson Junction is a weak connection between two superconductors. Josephson Junctions can be used to make a range of devices. Single Josephson Junctions can be used as photon detectors; arrays of Josephson Junctions in series can be used to build voltage standards; complex arrangements of Josephson Junctions can provide logical devices known as Rapid Single Flux Quantum (RSFQ) devices, comparable to semiconductor arrays of transistors, with four orders of magnitude less power consumption and a hundred times more rapid. A DC SQUID consists of two Josephson junctions connected in parallel on a superconducting loop.

Given the short characteristic length scale of a few nanometers in HTSc materials, making Josephson junctions for superconductor devices based on these materials on a scale comparable thereto can be rather challenging.

Efforts have been invested in the development of Josephson junctions with artificial barriers. Most high T_{c} SQUIDs are made with bicrystal grain boundary junctions which are fabricated by epitaxial growth of a high T_{c} thin film on a bicrystal substrate with a given misorientation angle. Although these junctions have yielded good performance, reproducibility from junction to junction is poor, due to difficulties in controlling grain boundary characteristics. The variability in the bicrystal substrates also increases the spread of junctions' parameters from chip to chip. In addition, the long-term stability of these devices is not guaranteed, due to oxygen diffusion along the grain boundary. Moreover, they are serious design constraints since the junctions have to be aligned along the grain boundary. It is therefore difficult to make arrays or more complex structures including a great number of SQUIDs. The cost of the bicrystal substrates is an obstacle for mass production of HTSc SQUIDs.

U.S. Pat. No. 5,026,682, incorporated herein by reference, describes a method of making a SQUID using high Tc superconductors. A superconducting loop having superconducting weak links is formed to comprise the SQUID device. The superconducting weak links are formed of the same superconductive material as the loop but have a narrower current path. This is a major issue: the width of the narrow region has to be of the order of the coherence length, i.e. 1 to 2 nm for HTSC. These weak links are difficult to form on complex material and thus unstable. A major drawback of the SQUIDs described in this document is that the devices have low sensitivity and do not demonstrate controllable and reproducible properties.

### SUMMARY OF THE INVENTION

A first aspect of the invention provides a method of making a superconductor device, the method comprising forming, in a vacuum, a layer of superconductive material; forming, in situ, a mask over part of the layer of superconductive material; irradiating the layer of superconductive material through the mask with ions such that a first portion having superconductive properties and a second portion having non superconductive properties are formed in the layer of superconductive material, the mask overlying the first portion.

A second aspect of the invention provides a method of making a superconductor device having at least one Josephson Junction, comprising the steps of forming a layer of superconductive material, forming a first mask over part of the layer of superconductive material, irradiating the layer of superconductive material through the first mask with first ions such that a first portion having superconductive properties and a second portion having electrical insulating properties are formed in the layer of superconductive material, the first mask overlying the first portion, forming a second mask over a part of the first portion of the superconductive layer, defining a slit in the second layer of masking material, and irradiating the layer of superconductive material through the second mask with second ions to disorder atoms in a portion of the layer of superconductive material underlying the slit such that the critical superconducting temperature of the part of the first portion of layer of superconductive material exposed through the slit is lowered relative to the critical superconducting temperature of a part of the first portion of the superconductive layer protected by the second mask.

A third aspect of the invention provides a superconductor device comprising a layer of superconductive material having at least one first region formed therein exhibiting superconductive properties and at least one second region formed therein exhibiting non superconductive properties or electrical insulating properties relative to the first region, at least one connector for passing a superconducting electrical current through the at least one first region, and at least one junction formed within the at least one first region, the junction having a lowered transition temperature relative to the transition temperature of the first region.

A fourth aspect of the invention provides a superconducting quantum interference device (SQUID) comprising a layer of superconductive material having at first region therein forming a loop exhibiting superconductive properties and a second region surrounding the loop exhibiting electrical insulating properties relative to the first region; at least one connector for passing a superconducting electrical current through the first region; and at least one Josephson junction formed within the loop, the junction Josephson having a lowered critical superconducting temperature relative to the critical superconducting temperature of the first region.

A fifth aspect of the invention provides a method of making a magnetic circuit device, the method comprising: forming a layer of manganite material; forming a mask over part of the layer of manganite material; and irradiating the layer of manganite material through the mask with ions such that a portion of the layer of manganite material not underlying the mask has its conductive properties altered by the ions.

A sixth aspect of the invention provides a magnetic circuit device comprising: a layer of manganite material having at least one first region formed therein exhibiting electrical conductive properties and at least one second region formed therein exhibiting electrical insulating properties relative to the first region; at least one connector for passing an electrical current through the at least one first region; and at least one junction formed within the at least one first region, the junction having a higher resitivity relative to the resistivity of the first region.

### BRIEF DESCRIPTION OF THE DRAWINGS

Embodiments of the invention will be described, by way of example only, with reference to the following drawings in which:

FIG. 1 is a general perspective view of an example of a SQUID according to an embodiment of the invention;

FIG. 2 is a schematic view of a method of making a superconductor device according to an embodiment of the invention;

FIG. 3 is a perspective view of the formation of a gold mask on a superconductor layer according to the embodiment of FIG. 2;

FIG. 4 is a perspective view of a current path formed in a superconductor layer according to the embodiment of FIG. 2;

FIG. 5 is a sectional view through line AA′ of FIG. 4;

FIG. 6 is a schematic view of a method of forming two Josephson junctions in a superconductor device according to an embodiment of the invention;

FIG. 7 is a sectional diagram of a method of forming a Josephson junction in the superconductor device of FIG. 6;

FIG. 8 shows a resistance versus temperature plot of a Josephson junction made in accordance with an embodiment of the invention;

FIG. 9 shows a critical current versus temperature plot of two different Josephson junctions made in accordance with an embodiment of the invention;

FIG. 10 shows a current versus voltage plot of a SQUID according to an embodiment of the invention;

FIG. 11 is a plot of voltage versus applied magnetic field of a SQUID according to an embodiment of the invention;

FIG. 12 is a plot of voltage versus applied magnetic field of a SQUID according to another embodiment of the invention;

FIG. 13 is a plot of SQUID modulations for larger values of the magnetic field than the ones plotted in FIG. 12;

FIG. 14 is a schematic view of a method of making a superconductor device according to a further embodiment of the invention; and

FIG. 15 is a schematic view of a method of making a superconductor device according to the embodiment of FIG. 14.

### DETAILED DESCRIPTION

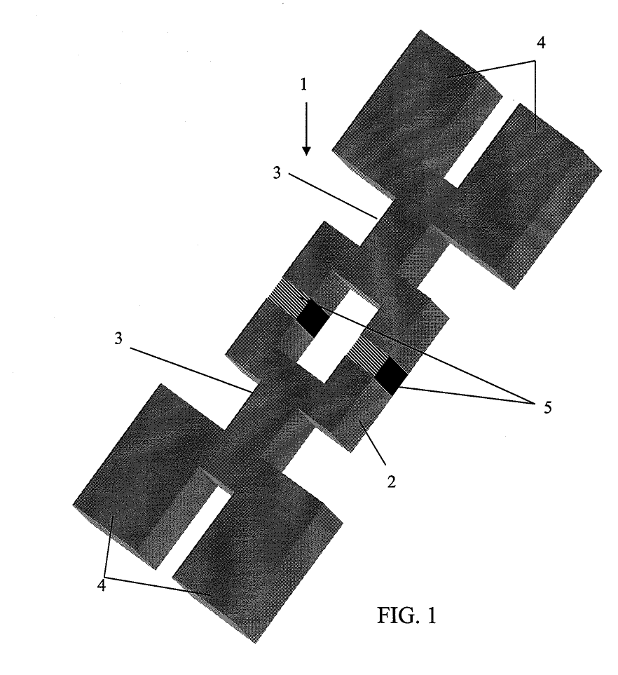

FIG. 1 generally illustrates an example of a DC SQUID which may be made according to the embodiments to be described. The SQUID 1 comprises a superconducting loop 2, having connecting lines 3 extending outwardly from parallel first opposing sides of the loop 2. The connecting lines 3 are provided at their ends, distal from the loop 2, with contact pads 4. Two Josephson Junctions 5 are symmetrically located on parallel second opposing sides of the superconducting loop 2.

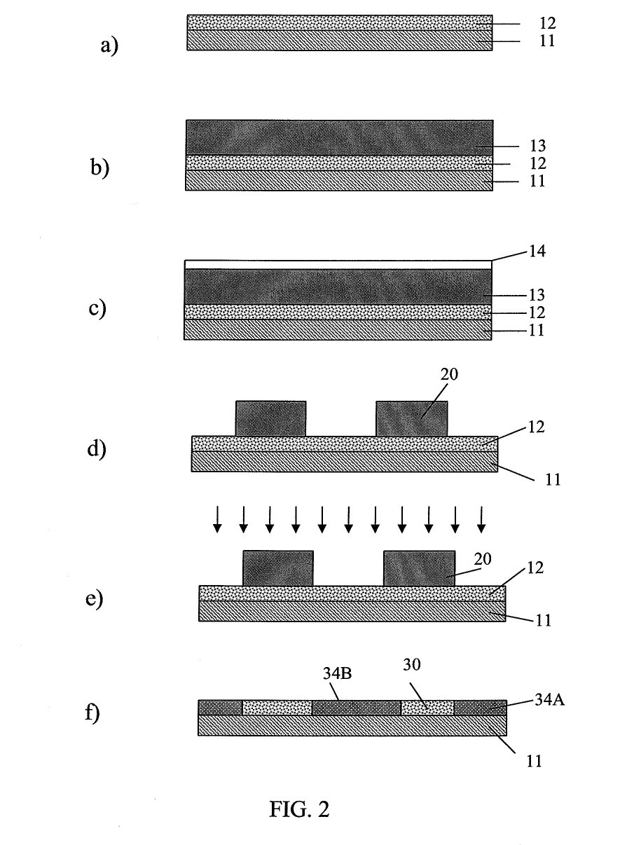

A method of making a SQUID according to a first embodiment will now be described with reference to FIGS. 2-5. In a vacuum chamber, a c-axis oriented YBa₂Cu₃O₆₊ₓ (YBCO) superconductor thin film 12 having a thickness in a range of from approximately 50 nm to approximately 500 nm, for example 150 nm, is deposited on a single crystal substrate of SrTiO₃ 11. This range of thickness of the superconductor layer can result in a more homogeneous profile of defects. Suitable epitaxial growth techniques for depositing the YBCO film 12 on the substrate 11 may include pulsed laser deposition, sputtering or coevaporation. As a starting material, the c-axis oriented film of oxide superconductor is available commercially and at a low cost.

In the same vacuum chamber, without breaking the vacuum, i.e. in situ, a gold layer 13 having a thickness in a range for from 100 nm to 500 nm, for example approximately 250 nm is deposited on the YBCO film 12 such that it covers the top surface of the YBCO film 12. The presence of the gold layer 13 protects the SQUID during the process of manufacture. Moreover, applying the gold layer in situ ensures a good electrical contact between the gold layer 13 and the YBCO film 12 resulting in both reproducible characteristics and low contact resistances to the resulting superconductor device through its contact pads, leading to a low noise device.

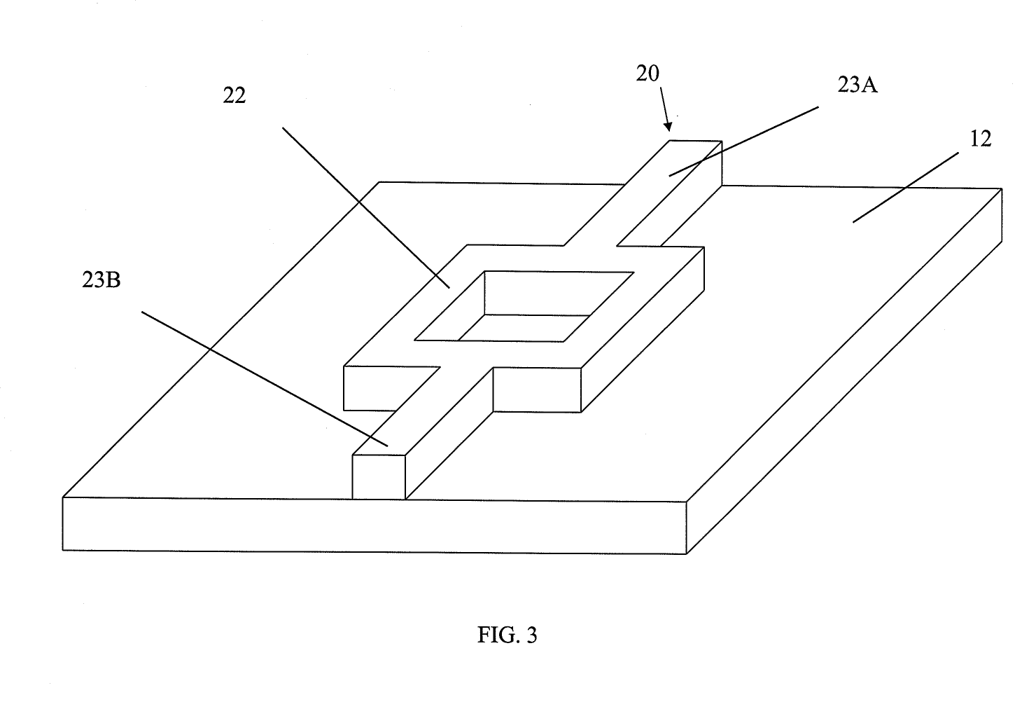

A layer of polymethylmethacrylate (PMMA) resist 14 is then deposited on the layer of gold 13. The thickness of the photo resist layer may be a range of from 500 nm to 1000 nm, for example, 800 nm. Electronic lithography is then used to pattern the desired SQUID geometry. The SQUID geometry of the present embodiment corresponds to the geometry illustrated in FIG. 3 and includes a loop 22 with two connecting lines 23A and 23B extending outwardly from opposing sides of the loop 22, and contact pads (not shown). Ar ion beam etching (IBE) is then used to remove gold from the areas outside the desired SQUID geometry leaving a gold mask 20 comprising the superconducting loop 22, the connecting lines 23A and 23B, and the contact pads on the YBCO film 12. In an alternative technique, the electronic lithography steps described above can be made by means of optical lithography (using UV, deep UV, double exposure technique, phase-shift mask technique or X-rays).

The YBCO film 12 is then irradiated with high energy ions through the gold mask 20. 100 keV oxygen ions at a high fluence F of approximately 5×10¹⁵ at/cm² may be used. The gold mask 20 prevents the implantation of the ions in regions of the YBCO film 12 corresponding to the SQUID geometry i.e. in regions of the YBCO film 12 underlying the gold mask 20. The atomic disorder induced by ion irradiation in the regions of the YBCO film 12 which are unprotected by the gold mask 20 lowers the transition temperature of the superconductive material 12 driving the oxide superconductors in the exposed regions towards a non superconducting and to an electrical insulating state. Although in this embodiment oxygen ions at an energy of 100 keV are used, in alternative embodiments different type of ions may be used. For example, in some embodiments, He, Ne, Cu, Ar, Xe or Kr ions may be used. The energy of irradiation may be adjusted to the nature of ions used in order to give the desired amount of defects in the unprotected region of the YBCO film 12. For example, ion energies ranging from 10 keV to 1 MeV may be used. The thickness of the gold layer 13 can be adjusted to be greater than the maximum penetration depth of ions with a given energy. After irradiation, the gold mask 20 is removed by a suitable technique such as chemical wet etching or by ion beam etching through a suitable resist mask, leaving the contact pads. Since no superconducting material is removed during the process, oxygen diffusion out of the resulting superconducting device is prevented thereby ensuring long term stability and cycling.

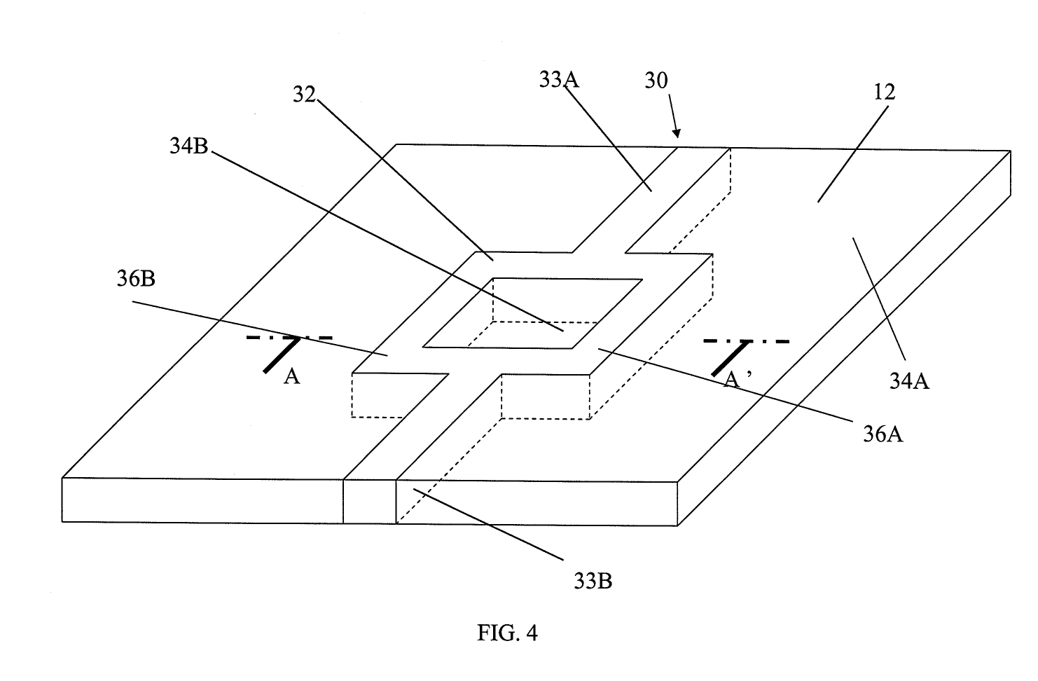

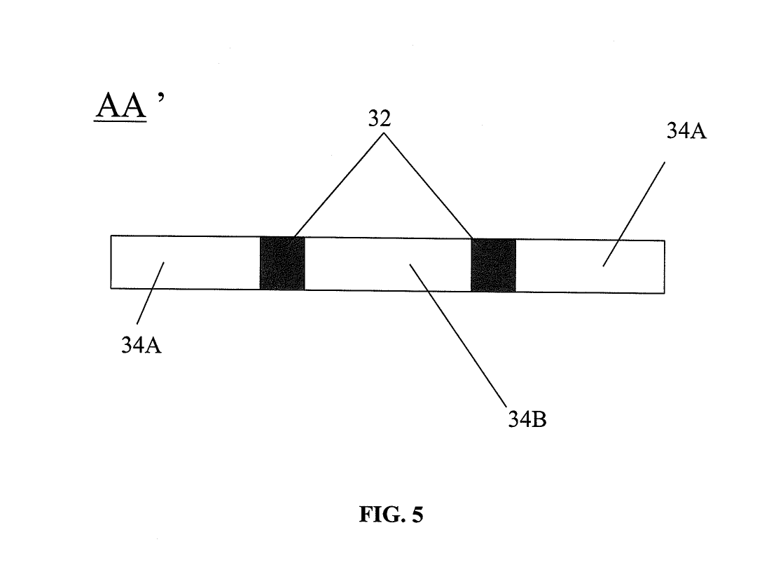

FIG. 4 is a perspective view illustrating the resulting geometry of the current path designed in the YBCO film 12. The resulting superconducting device 30 comprises a superconducting loop 32 and current paths or connectors 33A and 33B extending outwardly from opposing sides of the superconducting loop 32. The transition temperature T_{c} of the material in region 34A outside the superconducting loop 32 and in region 34B within the superconducting loop 32 is lowered by the ion irradiation such that these regions lose their superconducting properties relative to the superconducting properties of the loop 32 and become electrical insulating. FIG. 5 is a sectional view of a portion of the structure of FIG. 4 taken along the line AA′ showing the non superconducting regions 34A and 34B and the regions corresponding to a portion of the superconducting loop 32.

Since the resulting structure is a planar structure, no superconducting matter is removed during the process thereby preventing oxygen diffusion out of the resulting SQUID ensuring its long-term stability and cycling.

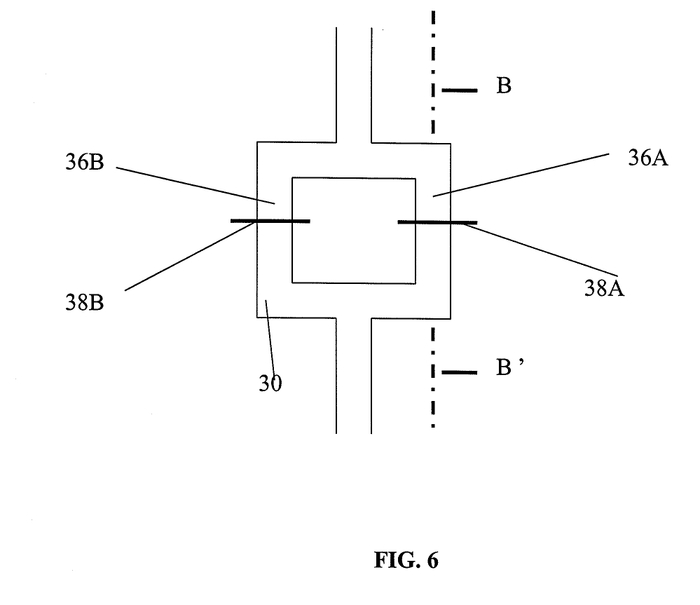

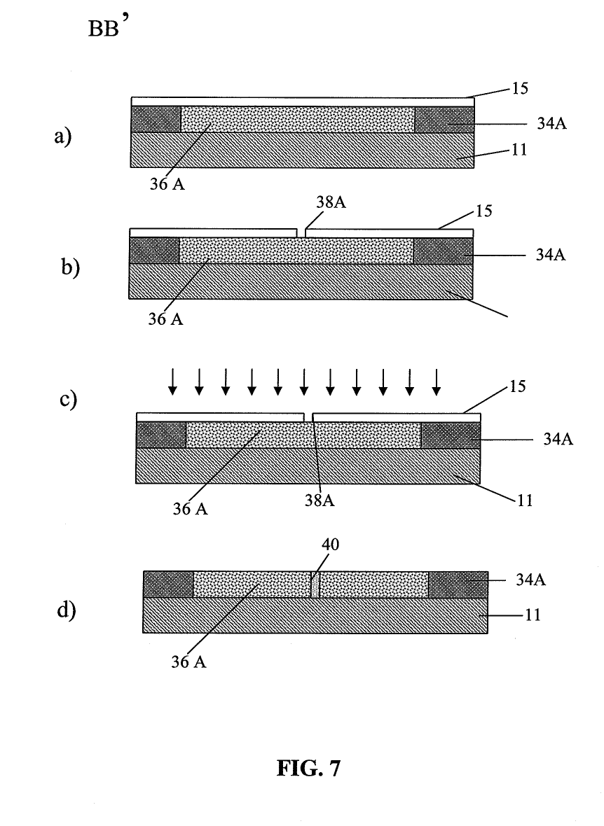

FIGS. 6 and 7 illustrate a process for creating Josephson junctions in the superconductor device 30 according to an embodiment. In this embodiment, the process involves creating Josephson junctions to symmetrically oppose each other in the superconducting loop 32 of the superconducting device 30 in order to form a SQUID device. The Josephson coupling can occur in the basal plane of the oxide superconductor.

A layer of PMMA photo resist 15 is deposited on the device 30 and two slits 38A and 38B, each approximately 20 nm wide, are defined in the photoresist 15 by electronic lithography across opposing arms 36A and 36B. The structure is than irradiated with 100 keV oxygen atoms with a typical fluence F of a few 10¹³ at/cm² e.g. 6. 10¹³ at/cm². Ion mass and energy, and photo resist thickness can be chosen such that the ions can be stopped by the photoresist layer thereby protecting the superconducting layer below.

The atomic disorder induced by ion irradiation drives superconductors oxide in the region 40 under the slit towards a non superconducting state thereby lowering the local superconducting transition temperature T_{c} in the region to a temperature T_{c}, and increasing the resistivity of the region 40 in a controllable and reproducible manner.

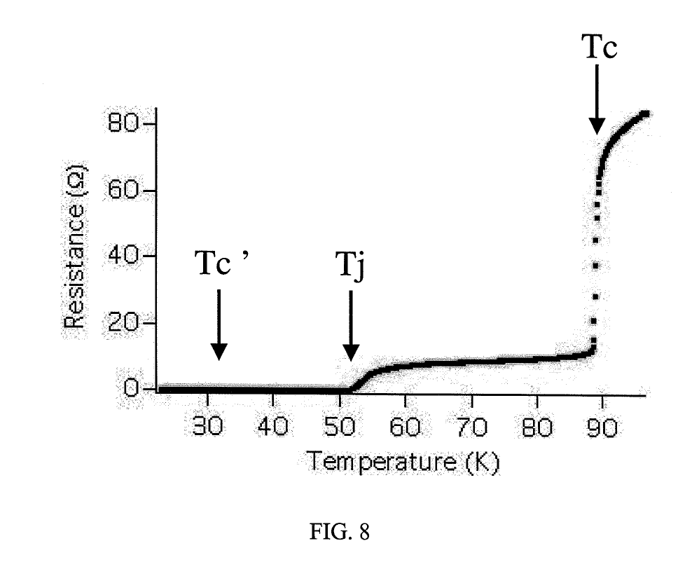

In this way, a superconducting-normal-superconducting junction 40 at temperatures between T_{c}′ and T_{c} is formed in the regions under the slits 38A. In this range of temperature, a clear Josephson coupling occurs at a temperature Tⱼ. FIG. 8 shows a resistance versus temperature plot of an example of a Josephson junction manufactured according to the method. In this case the Josephson junction has a width of 1 μm and is made with oxygen ion beam irradiation at a fluence of 6.10¹³ at/cm² and an energy of 100 keV through a 20 nm width slit.

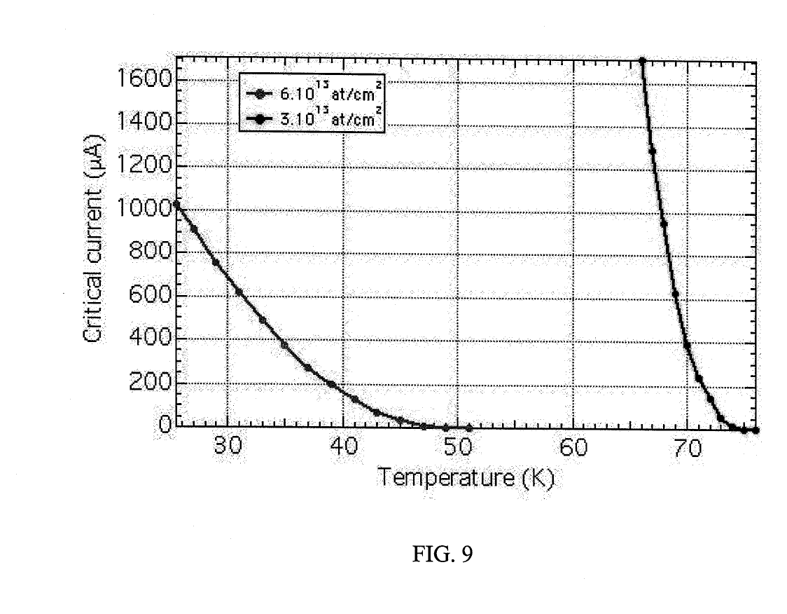

FIG. 9 shows a critical current versus temperature plot of an example of two Josephson Junctions manufactured according to the above-mentioned method with oxygen ion beam irradiation (energy 100 keV) through a 20 nm width slit for two different fluences 3.10¹³ at/cm² and 6.10¹³ at/cm². As illustrated in FIG. 9, below the temperature Tⱼ the Josephson critical current I_{c} increases quadratically as a function of temperature. The value of Tⱼ, and consequently the value of I_{c} at a given temperature, can be thus be tuned by choosing the right fluence of ions, their mass and the energy of irradiation. In an alternative embodiment the variation of Tⱼ can be obtained by changing the width of the slits. The width of the slit may be in a range of form 10 nm to 100 nm, for example.

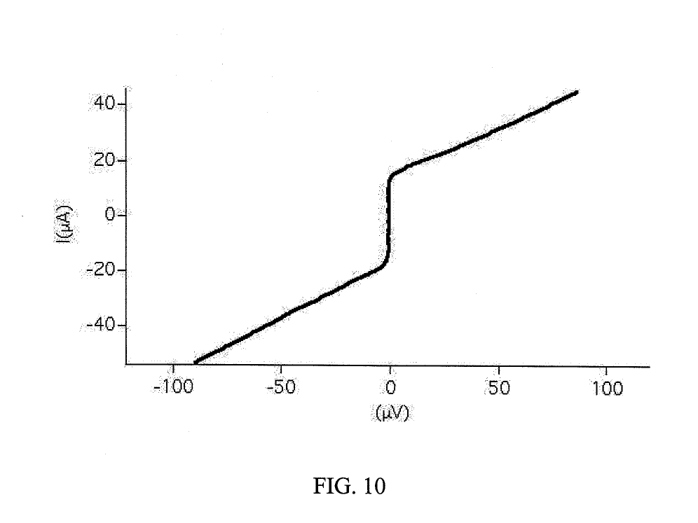

FIG. 10 shows the current versus voltage plot for a SQUID irradiated with a fluence of 6.10¹³ at/cm² (energy=100 keV)at a temperature T=43K. This DC SQUID shows a presence of a critical Josephson current in a range of temperature between T_{c}=32K and Tⱼ₌52K.

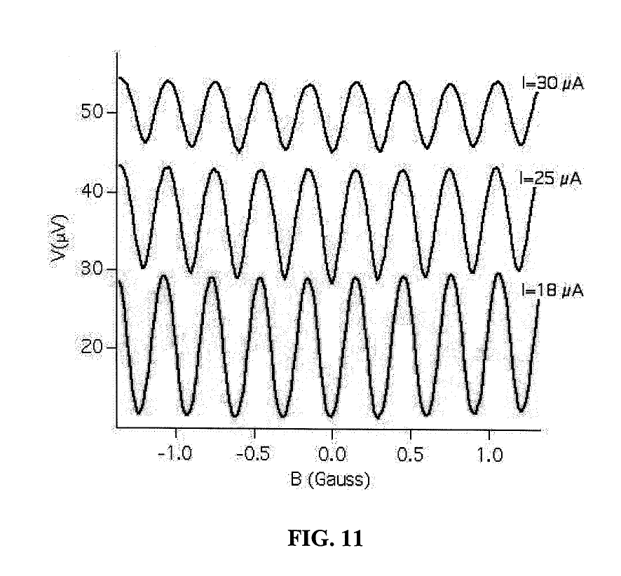

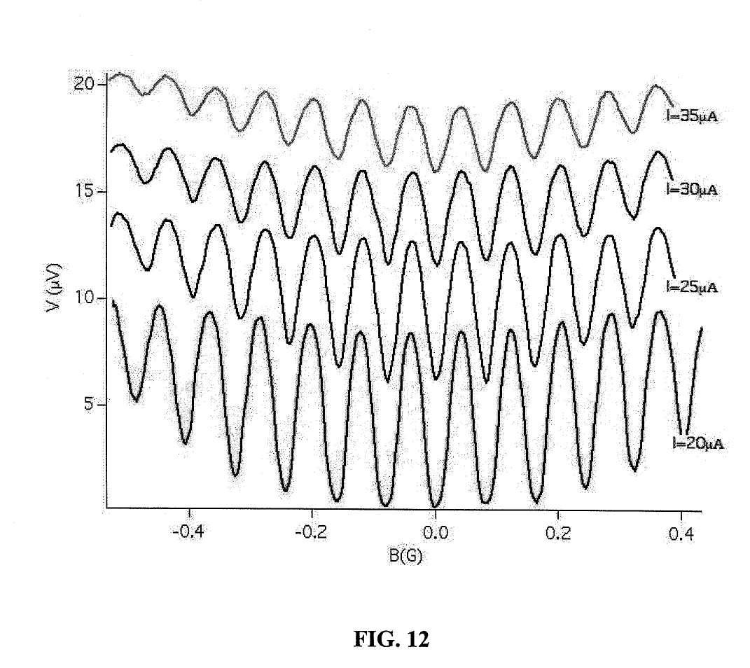

FIGS. 11 and 12 show plots of voltage versus an applied magnetic field perpendicular to the loop for two different SQUID geometries manufactured according to the method described above. FIG. 11 is a plot of voltage versus applied magnetic field of a SQUID with a 6.1 μm*6 μm superconducting loop and 2 μm width arms. FIG. 12 is a plot of voltage versus applied magnetic field of a SQUID with a 10 μm*10 μm superconducting loop and 5 μm width arms.

In FIGS. 11 and 12 different curves correspond to different values of the DC bias current greater than the critical current. The periodic dependence of the voltage as a function of magnetic field is characteristic of a SQUID operation. As expected, the period of modulations is related to the geometry of the loop. As the current bias is increased, the amplitude of the oscillation decreased. The screening of the superconducting part of the loop causes a “flux-focusing” effect, which slightly increases the magnetic field sensitivity.

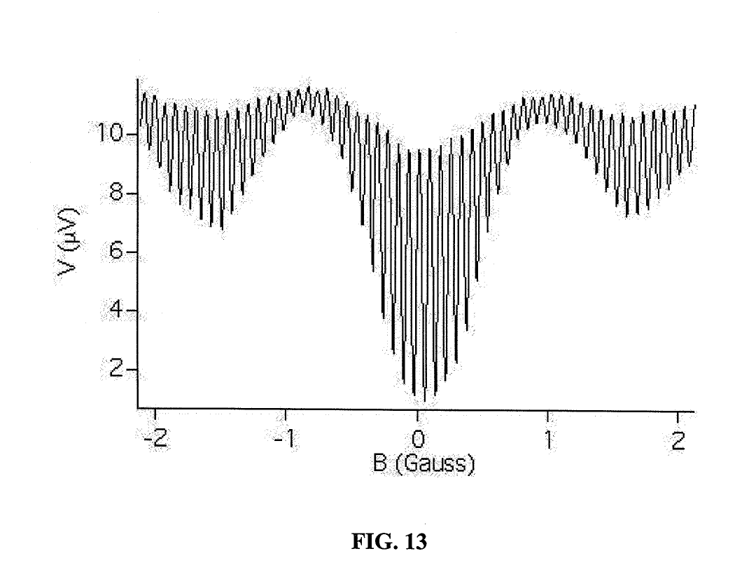

FIG. 13 is a plot of SQUID modulations for larger values of magnetic field than the values of FIG. 12. In addition to the SQUID modulations, it clearly shows the characteristic Fraunhofer patterns which demonstrates the quality of Josephson junctions.

For the manufacture of effective SQUIDs, it is necessary to make pairs of junction with identical characteristics. Using the method described above, the variation of characteristics from junction to junction on the same chip as well as variations of junctions from chip to chip can be small, for example less than 5%. Another property of the Josephson junctions manufactured by this method, compared to grain boundary junctions, is the ability to position the junction on the thin film without any geometrical constraints, allowing the fabrication of a high density of devices on a single substrate.

Regarding this aspect, it is worth mentioning that the methods described here allow highly reproducible Josephson Junctions to be made. Thus very complex circuits, as for example needed for RSFQ logic devices, can be made based on junctions having the very similar characteristics. This is a key point for the development of this promising technology, which has not yet emerged with HTSC, due to the spread in the junctions' characteristics (critical current, critical current density, normal state resistivity, Josephson coupling energy).

The junctions made in this way can carry high current densities (greater than 50 KA/cm²) giving high IcRn products (in the mV range), as required for RSFQ applications In absence of truly metallurgic interfaces in this type of junction, fluctuations of the critical current appear to be reduced which can enable SQUIDs with low noise (<10⁻¹⁰ V/Hz at 1 kHz) to be manufactured.

By choosing the irradiation characteristics (ion, energy, dose), the geometry of the SQUID and the geometry of the slits, the operating temperature, the critical current and the normal resistance of a SQUID manufactured according to this method can be finely tuned, in order to match the requirement of specific applications. In addition, the process can be highly scalable, without adding specific constraints for the manufacture of arrays and complex structures including numerous SQUIDs or other superconductor devices. Moreover, flux transformers and different controlled lines can be made using the first step of irradiation presented in the invention.

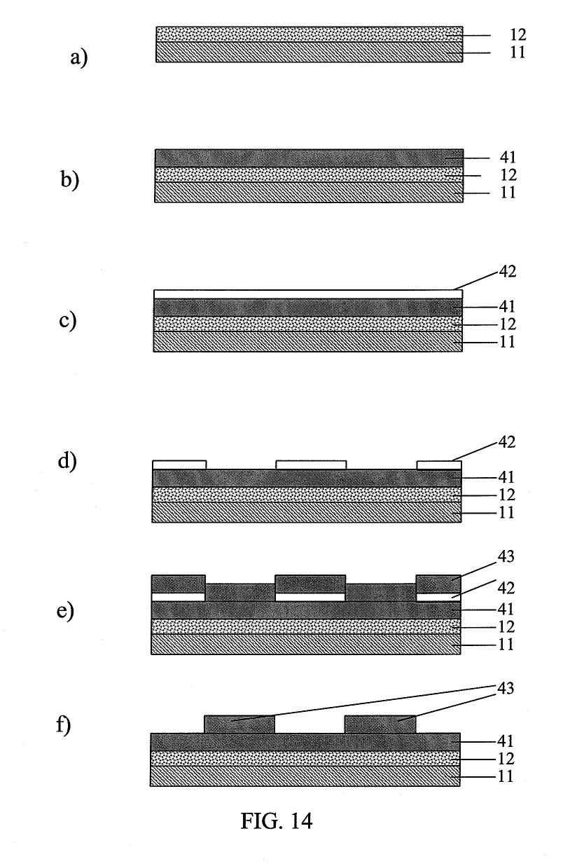

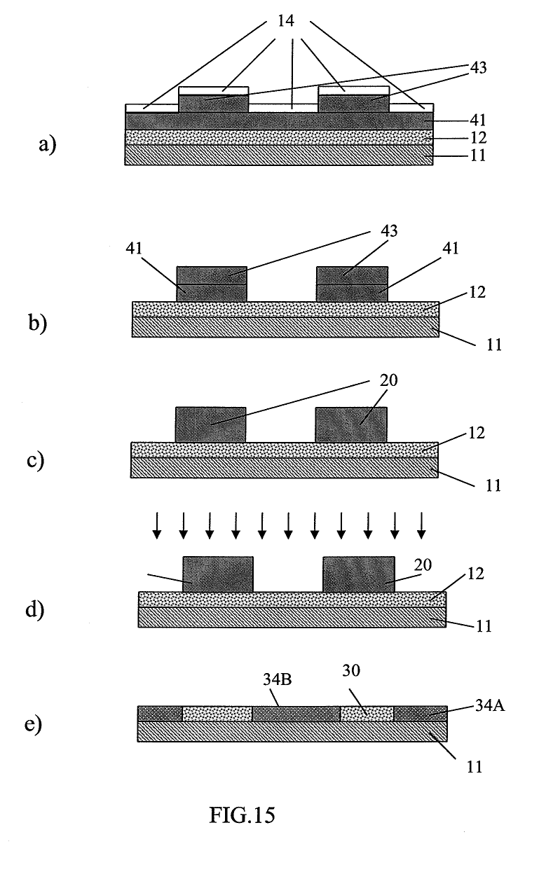

In an alternative embodiments a number of different layers of gold may be applied. An embodiment using a so called “lift-off technique” is illustrated in FIGS. 14 and 15. In this embodiment a 40 nm thick first gold layer 41 is deposited in situ on top of a layer of superconductive material 12 e.g. a c-axis oriented YBa₂Cu₃O₆₊ₓ superconductor film in the same vacuum chamber. The thickness of the first gold layer 41 may be in a range of from 20 to 100 nm. A PMMA photoresist layer 42 is then deposited on top of the first gold layer 41. The thickness of the photo resist layer 42 may be in a range of from 500 nm to 1000 nm, for example, 800 nm. Electronic lithography is used to pattern the desired SQUID geometry in the photo resist layer 42. The SQUID geometry of the embodiment corresponds to the geometry illustrated in FIG. 3 and includes a loop 22 with two connecting lines 23A and 23B extending outwardly from opposing sides of the loop 22, and contact pads (not shown). The PMMA photoresist layer 42 is opened to expose part of the first layer of gold 41 to correspond to the gold mask 20 geometry as shown in stage d) of FIG. 14. A 210 nm thick second layer of gold 43 is then deposited on the whole structure. The thickness of the second gold layer 43 may be such that the total gold thickness (layer 41 and layer 43) is around 250 nm. A lift-off is made, so that the second gold layer 43 is removed from regions outside the SQUID geometry as shown in FIG. 14 f.

A layer of polymethylmethacrylate (PMMA) resist 14 is then deposited on the remaining portion of layer of gold 43 and exposed regions of the gold layer 41 as illustrated in FIG. 15a). The thickness of the photo resist layer 14 may be a range of from 500 nm to 1000 nm, for example, 800 nm. Electronic lithography is then used to pattern the desired SQUID geometry and portions of the first gold layer 41 outside the desired SQUID geometry are removed. In this embodiment, the remaining ensemble of layers 41+43 as illustrated in stage FIG. 15 b plays the same role as the gold mask 20 as described above with reference to FIGS. 2 and 3, as illustrated in FIG. 15 c). Ion irradiation of the structure is carried out as described above and a Josephson junction may be incorporated in the resulting superconducting device as described above.

It will be appreciated that the electronic lithography steps of the so-called “lift-off technique” can be also made by mean of optical lithography (using UV deep UV, double exposure technique, phase-shift mask technique or X-rays).

An example of such a technique is described in document “High Tc superconducting quantum interference devices made by ion irradiation”—APL 89, 112515 (2006), which is incorporated herein by reference. The application of such a technique for the manufacture of Josephson junctions is described in the document “High quality planar high-Tc Josephson junctions”—APL 87, 102502 (2005), which is also incorporated herein by reference.

Although YBCO film was used as superconducting material in the embodiment described above, it will be appreciated that the above-described methods can be applied to a SQUID made of any oxide superconductor film material and not only to SQUIDs formed of a yttrium based compounds. This includes SQUIDs formed of other copper oxide type compound oxide superconductor thin film, including the so called Bismuth type compound oxide superconductor and thallium type compound oxide superconductor. Moreover, the method is not restricted to the use of oxide superconductors, other suitable superconductive materials may be used.

In addition, although in these embodiments the substrate used was a single crystal, SrTiO₃ substrate, it will be appreciated that any insulating substrate which is suitable for growing c-axis oriented oxide superconductors may be used. Other examples of substrates include perovskites such as LaAlO₃, MgO, CeO₂, NdGaO₃, sapphire, Y-stabilized Zirconia etc or thin layers (ranging from 10 to 100 nm) of these materials deposited on top of single crystals of the others, for example CeO₂/MgO, or even SrTiO₃/CeO₂/MgO etc. . . .

It will also be appreciated that instead of using a superconductor film on a substrate the superconductor material may be bulk material.

It will be appreciated that different geometries can be used to define SQUIDS and superconducting other devices. Some example of SQUID geometries made according to this method are a SQUID having a superconducting loop of approximately 1000 μm² with a 5 μm arm width corresponding to an inductance of L1=32 pH and a SQUID having a superconducting loop of approximately 36 μm² with a 2 μm arm width corresponding to an inductance of L2=17 pH.

While in the embodiments described above PMMA photoresist is used to define the geometry of the device, it will be appreciated that any suitable masking material for defining a pattern may be used. Other suitable photoresists, for example, include AZ type, Shippley Type, and trilayers AZ/Ge/PMMA materials.

It will also be appreciated that in alternative embodiments of the invention the layer of gold may be replaced by other suitable materials exhibiting suitable properties of electrical conductivity and/or masking, for example, silver or copper. The thickness of the layer may be varied accordingly.

The above-described methods employing high Tc superconductivity can be used to manufacture a wide range of novel electronic devices having advantageous and unique features. The lossless conductivity can be employed to make interconnections and passive devices such as high Q value filters, transition edge photon or current detectors.

In these cases, a technology suitable for enabling thin films of High Temperature Superconductors (HTSc) to be easily patterned is of great interest. Standard lithography suffers from lack of reproducibility and long term stability, when it comes to small dimensions typically in the range of microns. The above-described method can also employ the quantum nature of superconductivity to make active devices based on the control of the quantum phase of electrons through Josephson Junctions (JJ), and on the quantization of the magnetic flux in a superconductor (Φ₀=h/2e).

Although methods of making an electrical device was described above with reference to the manufacture of a SQUID, it will be understood that the methods may be applied to the manufacture of various superconductor or electronic devices with or without Josephson Junctions. Such superconductor devices may include interconnecting circuits, High Q value filters, transition edge photon or current detectors, voltage standards and RSFQ devices, magnetometers and voltmeters. These devices will be operated at temperatures below the Tc of the chosen superconductor. The operating temperature (or temperature range) itself, can be finely tuned by choosing the ion irradiation parameters: this is specific to this method of making superconductive electronic devices.

It will also be appreciated that the method of making a superconductor device and the method of making a Josephson junction can be applied independently. The method may be used to make a superconductor device not having a Josephson junction, and a Jospephson junction may be formed in a layer of superconductive material formed by another technique.

Furthermore, steps of the method can be applied to the manufacture of magnetic circuits. In as further embodiment of the method, a manganite film, for example LaₓSr₁₋ₓMnO₃ or LaₓCa₁₋ₓMnO₃, (with 0≦x≦1) is formed on a single crystal substrate such as SrTiO₃. A gold mask is used, as previously described to design the desired circuit geometry and the structure is irradiated with ions which may be oxygen ions having an energy of 100 keV and a fluence of 5×10¹⁵ at/cm². The ions causes a degree of disorder in the manganite film not protected by the gold mask and thus exposed to the ion beam thereby altering the properties of the manganite material in these regions rendering it insulating so that current can be concentrated in the areas of manganite material protected by the gold mask.

Such circuits may find applications in fields such as spintronics. Spintronics is the manipulation of information from electron spins as opposed to their charges.

In some examples of magnetic circuits manufactured according to an embodiment, a tunnel junction or equivalent, for example, a magnetic tunnel junction may be formed in the circuit. Such a tunnel junction may be manufactured in the a similar way to the manufacture of a Josephson junction as described above by irradiating the manganite film with ions though a photoresist mask (e.g. PMMA) having a slot of approximately 20 nm, using an ion fluence in a range of approximately 10¹³ or 10¹⁴ at/cm².

It will be appreciated that the methods described here to make superconductive and/or magnetic electrical devices are compatible with the current industrial technological processes used in the semiconductor electronic industry (lithography, patterning, etching, layer deposition, ion-irradiation . . . )

Further modifications lying within the spirit and scope of the present invention will be apparent to a skilled person in the art.

1. A method of making a superconductor device, the method comprising:
forming, in a vacuum, a layer of superconductive material;
forming, in the same vacuum, a mask over part of the layer of superconductive material;
irradiating the layer of superconductive material through the mask with ions such that a first portion having superconductive properties and a second portion having electrical insulating properties are formed in the layer of superconductive material, the mask overlying the first portion.

2. A method according to claim 1, wherein forming a mask over the layer of superconductive material comprises:
depositing a layer of masking material over the layer of superconductive material;
depositing a layer of photoresist over the layer of masking material; and
etching the mask in the masking material through the layer of photoresist.

3. A method according to claim 2, wherein the masking material comprises gold.

4. A method according to claim 3, wherein the layer of masking material has a thickness in a range of from 100 nm to 500 nm.

5. A method according to claim 4, wherein the layer of masking material has a thickness of approximately 250 nm.

6. A method according to claim 1, wherein the superconductive material is an oxide superconductor.

7. A method according to claim 1, wherein forming a layer of superconductive material comprises forming a film of superconductive material on a substrate.

8. A method according to claim 7, wherein the film of superconductive material is a c-axis oriented YBa₂Cu₃O₆₊ₓ superconductor film.

9. A method according to claim 7, wherein the thickness of the layer of superconductive material is in a range of from 50 nm to 500 nm.

10. A method according to claim 11, wherein the thickness of the layer of superconductive material is approximately 150 nm.

11. A method according to claim 7, wherein the substrate comprises a perovskite.

12. A method according to claim 7, wherein the substrate is a single crystal substrate.

13. A method according to claim 11, wherein the substrate comprises at least one material selected from the group consisting of SrTiO₃, LaAlO₃, Y—ZrO₂, CeO₂ and MgO.

14. A method according to claim 1, wherein the ions are oxygen ions.

15. A method according to claim 14, wherein the energy of the oxygen ions is in a range of from 10 keV to 1 MeV.

16. A method according to claim 15, wherein the energy of the oxygen ions is approximately 100 keV.

17. A method according to claim 1, wherein the fluence of ions is in a range of from 1.10¹⁵ at/cm^{2 to} 1.10¹⁶ at/cm².

18. A method according to claim 17 wherein the fluence of ions is approximately 5.10¹⁵ at/cm².

19. A method according to claim 1, further comprising forming at least one Josephson junction in the layer of superconductive material by
removing part of the mask such that at least a portion of the mask is left to constitute at least one electrical contact point;
depositing a second layer of masking material on the layer of superconductive material;
defining a slit in the second layer of masking material;
irradiating the layer of superconductive material through the second layer of masking material with further ions to disorder atoms in a portion of the layer of superconductive material underlying the slit such that the critical superconducting temperature of the portion of layer of superconductive material exposed through the slit is lowered relative to the critical superconducting temperature of the portion of the layer of superconductive material protected by the second layer of masking material.

20. A method according to claim 19, wherein the second layer of masking material is a photoresist.

21. A method according to claim 20, wherein the photo resist is PMMA.

22. A method according to claim 19, wherein the slit has a width in a range of from approximately 100 nm to 100 nm.

23. A method according to claim 19, wherein the further ions are oxygen ions.

24. A method according to claim 23, wherein the energy of the further ions is in a range of from 10 keV to 1 MeV.

25. A method according to claim 19, wherein the fluence of the further ions is in a range of from 1.10¹³ at/cm² to 1.10¹⁵ at/cm².

26. A method of making a superconductor device having at least one Josephson Junction, the method comprising:
forming a layer of superconductive material;
forming a first mask over part of the layer of superconductive material;
irradiating the layer of superconductive material through the first mask with first ions such that a first portion having superconductive properties and a second portion having electrical insulating properties are formed in the layer of superconductive material, the first mask overlying the first portion;
forming a second mask over at least a part of the first portion of the layer of superconductive material;
defining a slit in the second mask; and
irradiating the layer of superconductive material through the second mask with second ions to disorder atoms in a portion of the layer of superconductive material underlying the slit such that the critical superconducting temperature of the portion of layer of superconductive material exposed through the slit is lowered relative to the critical superconducting temperature of the portion of the layer of superconductive material protected by the second mask.

27. A method according to claim 26, wherein the steps of forming a layer of superconductive material and forming a first mask over part of the layer of superconductive material are carried out in the same vacuum.

28. A method according to claim 26, wherein the first mask comprises gold.

29. A method according to claim 28, wherein the first mask has a thickness in a range of from 100 nm to 500 nm.

30. A method according to claim 26, wherein the superconductive material is an oxide superconductor.

31. A method according to claim 30 wherein the superconductive material is a c-axis oriented YBa₂Cu₃O₆₊ₓ superconductor film.

32. A method according to claim 30, wherein the superconductive material is provided on a perovskite substrate.

33. A method according to claim 26, wherein the first ions are oxygen ions.

34. A method according to claim 26, wherein the energy of the first ions is in a range of from 10 keV to 1 MeV.

35. A method according to claim 34, wherein the fluence of the first ions is in a range of from 1.10¹⁵ at/cm^{2 to} 1.10¹⁶ at/cm².

36. A method according to claim 26 wherein forming the second mask comprises removing at least a portion of the first mask to expose at least a portion of the layer of superconductive material; and
depositing a second layer of masking material over at least part of the layer of superconductive material.

37. A method according to claim 36, wherein the second layer of masking material comprises a photoresist.

38. A method according to claim 26, wherein the slit has a width in a range of from approximately 10 nm to 100 nm.

39. A method according to claim 26, wherein the second ions are oxygen ions.

40. A method according to claim 39, wherein the energy of the second ions is in a range of from 10 keV to 1 MeV.

41. A method according to claim 40, wherein the fluence of the second ions is in a range of from 1.10¹³ at/cm² to 1.10¹⁵ at/cm².

42. A method according to claim 26, wherein the superconductor device comprises a SQUID.

43. A superconductor device comprising;
a layer of superconductive material having at least one first region formed therein exhibiting superconductive properties and at least one second region formed therein exhibiting electrical insulating properties relative to the first region;
at least one connector for passing a superconducting electrical current through the respective at least one first region; and
at least one Josephson junction formed within the at least one first region, the junction having a lowered critical superconducting temperature relative to the critical superconducting temperature of the first region.

44. A superconductor device according to claim 43, wherein the layer of superconductive material is an oxide superconductor.

45. A superconductor device according to claim 43, wherein the layer of superconductive material has a thickness in a range of from 50 nm to 500 nm.

46. A superconductor device according to claim 45, wherein the layer of superconductive material has a thickness of approximately 150 nm.

47. A superconductor device according to claim 43, wherein the layer superconductive material is a c-axis oriented YBa₂Cu₃O₆₊ₓ superconductor film.

48. A superconducting quantum interference device (SQUID) comprising:
a layer of superconductive material having at first region therein forming a loop exhibiting superconductive properties and a second region surrounding the loop exhibiting electrical insulating properties relative to the first region;
at least one connector for passing a superconducting electrical current through the first region;
at least one Josephson junction formed within the loop, the junction Josephson having a lowered critical superconducting temperature relative to the critical superconducting temperature of the first region.

49. A SQUID according to claim 48 wherein the SQUID includes two Josephson junctions so as to constitute a DC SQUID.

50. A SQUID according to claim 48, wherein the layer of superconductive material is an oxide superconductor.

51. A SQUID according to claim 48, wherein the layer of superconductive material has a thickness in a range of from approximately 50 nm to approximately 500 nm.

52. A SQUID according to claim 51, wherein the layer of superconductive material has a thickness of approximately 150 nm.

53. A SQUID according to claim 48, wherein the layer superconductive material is a c-axis oriented YBa₂Cu₃O₆₊ₓ superconductor film.

54. A method of making a magnetic circuit device, the method comprising:
forming a layer of manganite material;
forming a mask over part of the layer of manganite material;
irradiating the layer of manganite material through the mask with ions such that a portion of the layer of manganite material not underlying the mask has its electrical conductive properties altered by the ions such that it is driven towards an insulating state.

55. A method according to claim 54, wherein forming a layer of manganite material and forming a mask over part of the layer of manganite material is carried out in the same vacuum.

56. A method according to claim 54, wherein the mask comprises gold.

57. A method according to claim 54 wherein the manganite material is selected from the group consisting of LaₓSr₁₋ₓMnO₃ and LaₓCa₁₋ₓMnO₃.

58. A method according to claim 54, further comprising forming at least one junction in the layer of manganite material by
removing at least a portion of the mask;
depositing a second layer of masking material on the manganite layer
defining a slit in the second layer of masking material;
irradiating the manganite layer through the second layer of masking material to disorder atoms of a portion of the manganite layer underlying the slit such that the resistivity of the portion of manganite layer exposed through the slit is altered.

59. A logical device comprising at least one SQUID, according to claim 48.

60. A logical device according to claim 59, wherein the logical device is a rapid single flux quantum logic device.
